(19) United States
(12) Patent Application Publication
(10) Pub. No.: US 2026/0136551 A1
(43) Pub. Date: May 14, 2026

(54) FLASH MEMORY AND MANUFACTURING METHOD THEREOF

(71) Applicant: Winbond Electronics Corp., Taichung City (TW)

(72) Inventors: Po-Yen Hsu, Taichung City (TW); Ssu-Han Chen, Changhua County (TW); Chih-Sheng Chuang, Taichung City (TW)

(73) Assignee: Winbond Electronics Corp., Taichung City (TW)

(21) Appl. No.: 19/383,767

(22) Filed: Nov. 10, 2025

(30) Foreign Application Priority Data
Nov. 12, 2024 (TW) 113143284

(51) Int. Cl. H10B 41/30; H10B 41/43; H10D 30/01; H10D 30/68; H10D 62/10

(52) U.S. Cl. CPC H10B 41/30; H10B 41/43; H10D 30/0411; H10D 30/68; H10D 62/102

(57) ABSTRACT

Provided are a flash memory and a manufacturing method thereof. The flash memory includes a substrate, a first gate device, first doped regions, a first spacer, a capping layer, a hardmask layer, first contacts, a first protective layer, a second protective layer, a second gate device, second doped regions and a second spacer. The first protective layer is disposed between the first contacts and the hard mask layer, the capping layer and the first spacer. The second protective layer is disposed between the first protective layer and the first contacts, the capping layer, the first spacer and the substrate. The second gate device is disposed on the substrate in the peripheral region. The second doped regions are disposed in the substrate on two sides of the second gate device. The second spacer is disposed on the sidewall of the second gate device.

### CROSS-REFERENCE TO RELATED APPLICATION

This application claims the priority benefit of Taiwan application serial no. 113143284, filed on Nov. 12, 2024. The entirety of the above-mentioned patent application is hereby incorporated by reference herein and made a part of this specification.

### BACKGROUND

### Technical Field

The present invention relates to a flash memory and a manufacturing method thereof, and in particular to a flash memory in which the spacer on the sidewall of the gate device in the memory region and the spacer on the sidewall of the gate device in the peripheral region have different configurations and processes, and a manufacturing method thereof.

### Description of Related Art

In the current manufacturing process of a flash memory, while the spacer of the gate device in the memory region is formed, the spacer of the gate device in the peripheral region is also formed. For the gate device in the memory region, the design goal of the spacer is to reduce or prevent the leakage current from the word line to the bit line. For the gate device in the peripheral region, the design goal of the spacer is to control the electrical properties, the channel width, the operating speed, etc. Therefore, the goals of the above two are different. As the manufacturing process is scaled down, some problems arise from simultaneously forming the spacers of the gate devices in the memory region and the peripheral region. For example, when the number of spacer layers or the thickness of the spacer stack is increased to prevent the leakage current between the word line and the bit line, the increased complexity of etching the same spacer stack in the peripheral region tends to increase the electrical variation of the gate device with the lightly doped drain (LDD) in the peripheral region and reduce the operating speed.

In addition, after forming the spacers of the gate devices in the memory region and the peripheral region, doped regions are formed in the substrate on two sides of the gate devices in the memory region and the peripheral region in different steps. After forming the doped regions, a heat treatment is usually performed to diffuse the dopants in the doped regions. In the current process, multiple heat treatments are required, and when the heat treatment is performed on the doped regions in the memory region, the doped regions formed in the peripheral regions may be affected. Similarly, when the heat treatment is performed on the doped regions in the peripheral region, the doped regions formed in the memory region may also be affected. As a result, the thermal budget is increased, especially for the high-performance or the low-power flash memory, the yield is easily reduced.

### SUMMARY

The present invention provides a flash memory and a manufacturing method thereof, wherein a first protective layer and a second protective layer are disposed between the first contact and the first gate device in the memory region. The novel dual protective layer configuration provided by the present invention addresses the challenges associated with leakage current between the word line and the bit line, structural damage during spacer etching, and electrical variation in gate devices with lightly doped drains (LDD) in the peripheral region.

The flash memory of the present invention includes a substrate, a first gate device, first doped regions, a first spacer, a capping layer, a hardmask layer, first contacts, a first protective layer, a second protective layer, a second gate device, second doped regions and a second spacer. The substrate has a memory region and a peripheral region. The first gate device is disposed on the substrate in the memory region. The first doped regions are disposed in the substrate on two sides of the first gate device. The first spacer is disposed on a sidewall of the first gate device. The capping layer is disposed on a top surface of the first gate device. The hardmask layer is disposed on the capping layer. The first contacts are disposed on the first doped regions. The first protective layer is disposed between each of the first contacts and the hardmask layer, between each of the first contacts and the capping layer, and between each of the first contacts and the first spacer. The second protective layer is disposed between the first protective layer and the first contacts, between the first protective layer and the capping layer, between the first protective layer and the first spacer, and between the first protective layer and the substrate. The second gate device is disposed on the substrate in the peripheral region. The second doped regions are disposed in the substrate on two sides of the second gate device. The second spacer is disposed on a sidewall of the second gate device.

The manufacturing method of the flash memory of the present invention includes the following steps. A substrate having a memory region and a peripheral region is provided. A first gate device, a capping layer and a hardmask layer are formed in sequence on the substrate in the memory region. A first spacer is formed on a sidewall of the first gate device. First doped regions are formed in the substrate on two sides of the first gate device. A second gate device is formed on the substrate in the peripheral region. First contacts are formed on the first doped regions. A first protective layer is formed between each of the first contacts and the hardmask layer, between each of the first contacts and the capping layer, and between each of the first contacts and the first spacer. A second protective layer is between the first protective layer and the first contacts, between the first protective layer and the capping layer, between the first protective layer and the first spacer, and between the first protective layer and the substrate. A second spacer is formed on a sidewall of the second gate device. Second doped regions are formed in the substrate on two sides of the second gate device.

Based on the above, in the flash memory of the present invention, the first protective layer and the second protective layer are disposed between the first contact and the first gate device. This arrangement ensures that the first gate device is protected and maintains an appropriate distance between the first contact and the first gate device. The design helps to avoid leakage current during operation and prevents the first contact from coming into contact with the first gate device, the capping layer and the hardmask layer.

In addition, in the flash memory of the present invention, the first spacer located on the sidewall of the first gate device and the second spacer located on the sidewall of the second gate device may be formed of different materials and may have different configurations, and may be formed in different process steps. Therefore, the process steps in the peripheral region may be effectively simplified.

### BRIEF DESCRIPTION OF THE DRAWINGS

FIGS. 1A to 1I are schematic cross-sectional views of the flash memory of the embodiment of the present invention at different manufacturing stages.

### DESCRIPTION OF THE EMBODIMENTS

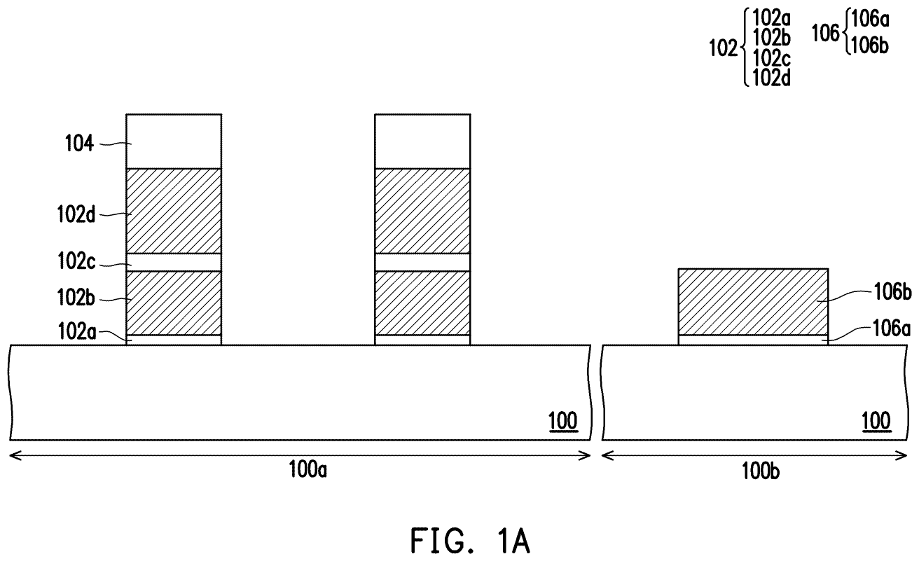

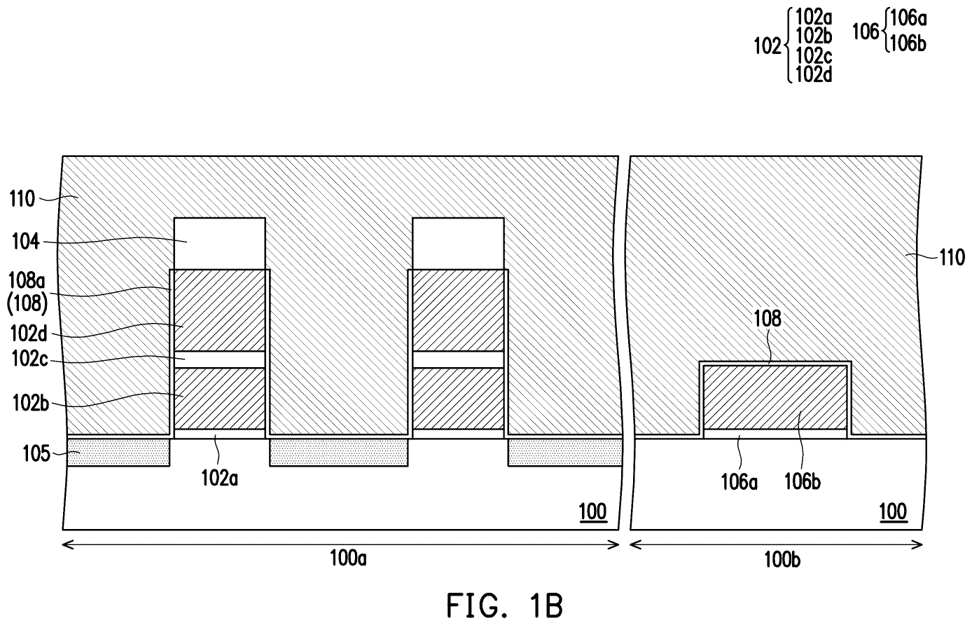

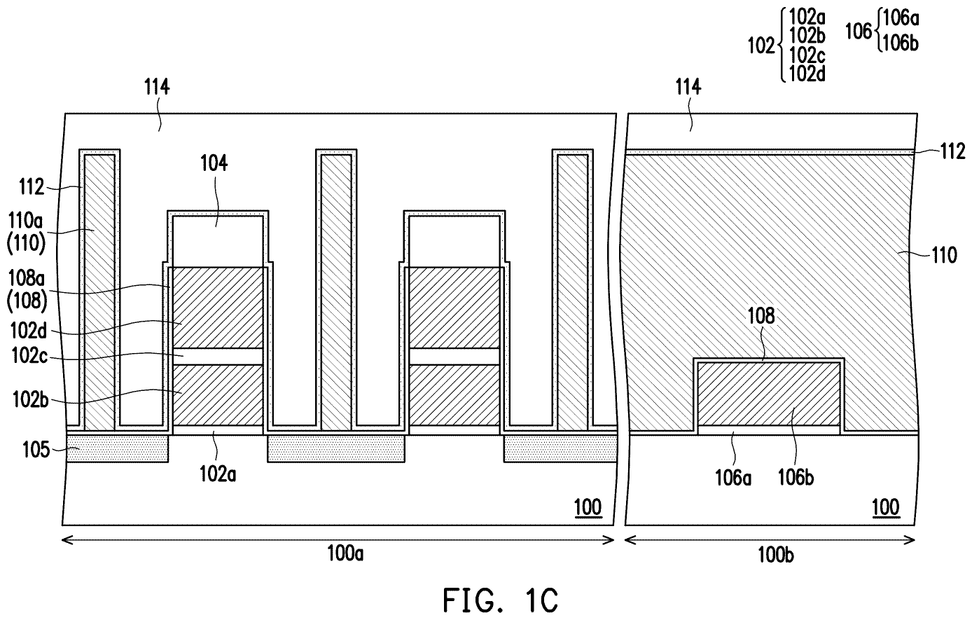

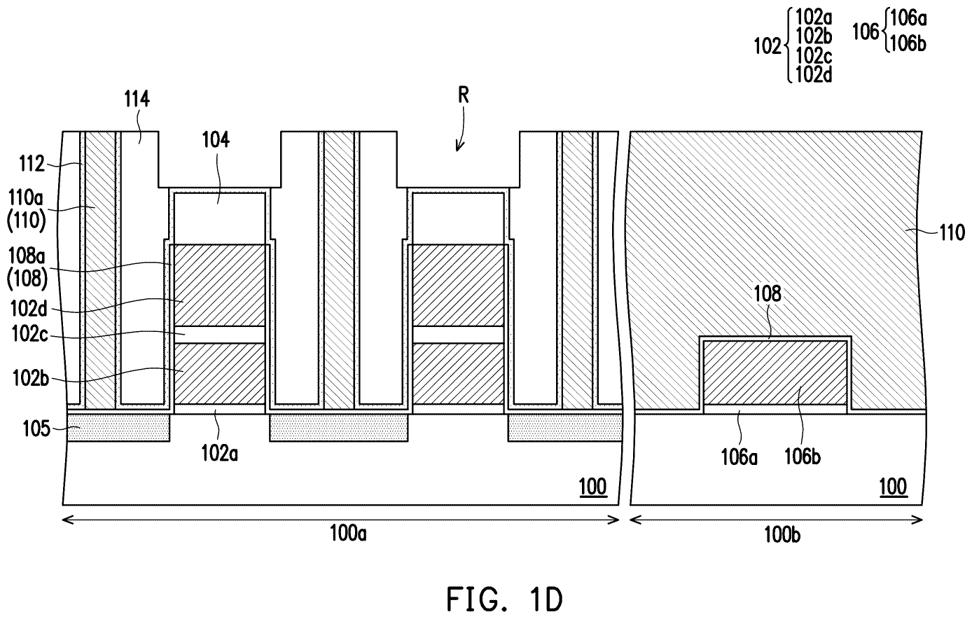

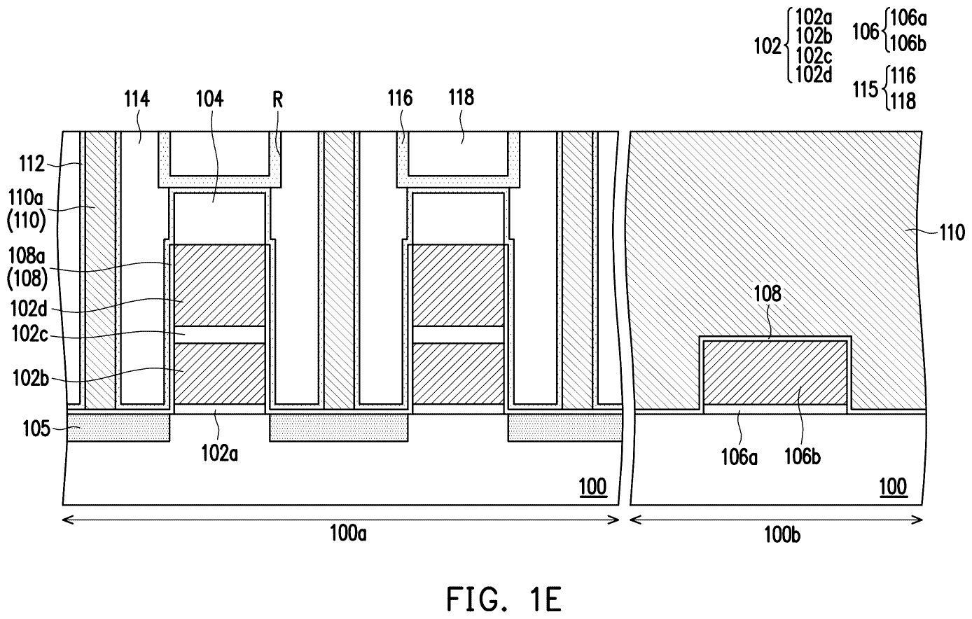

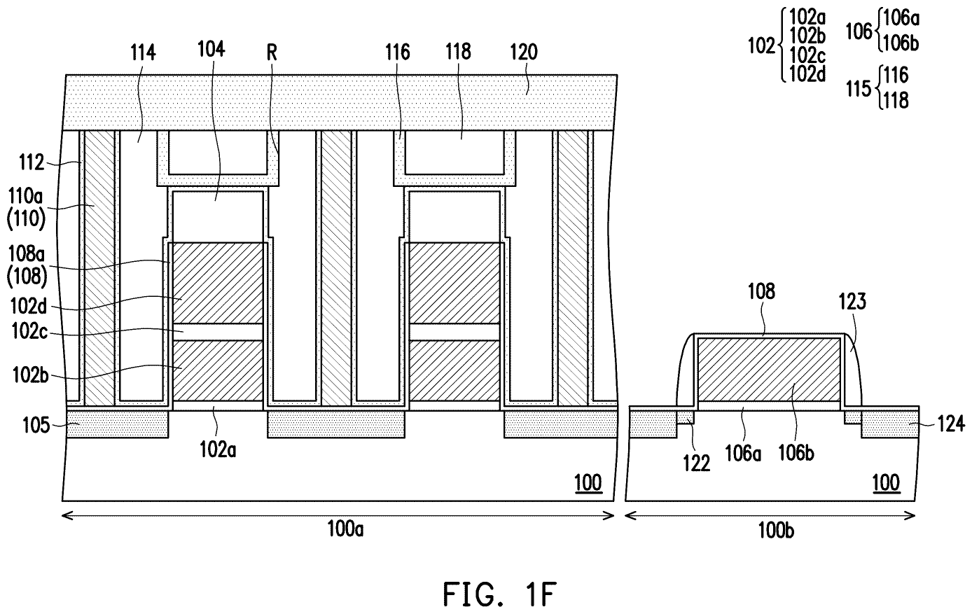

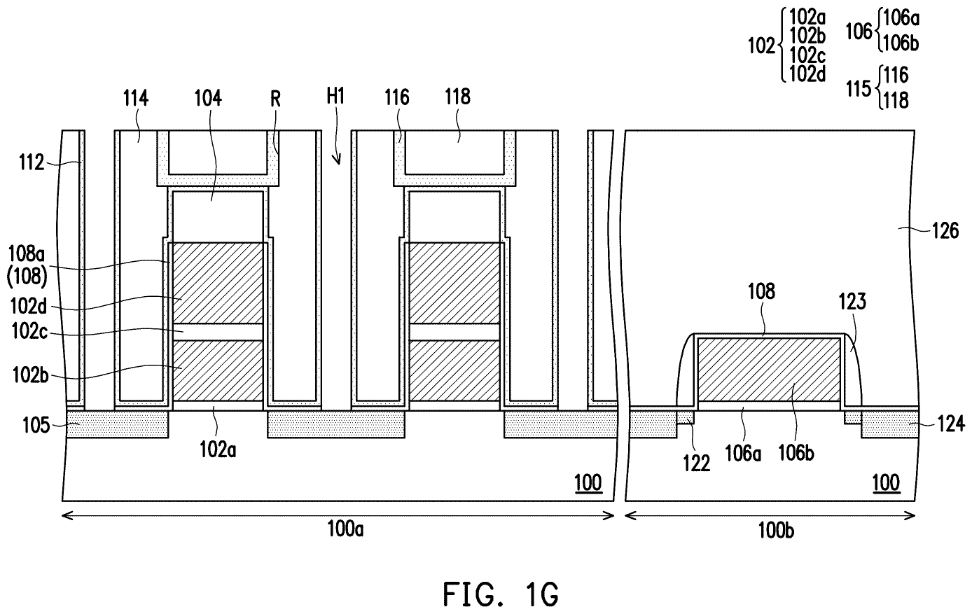

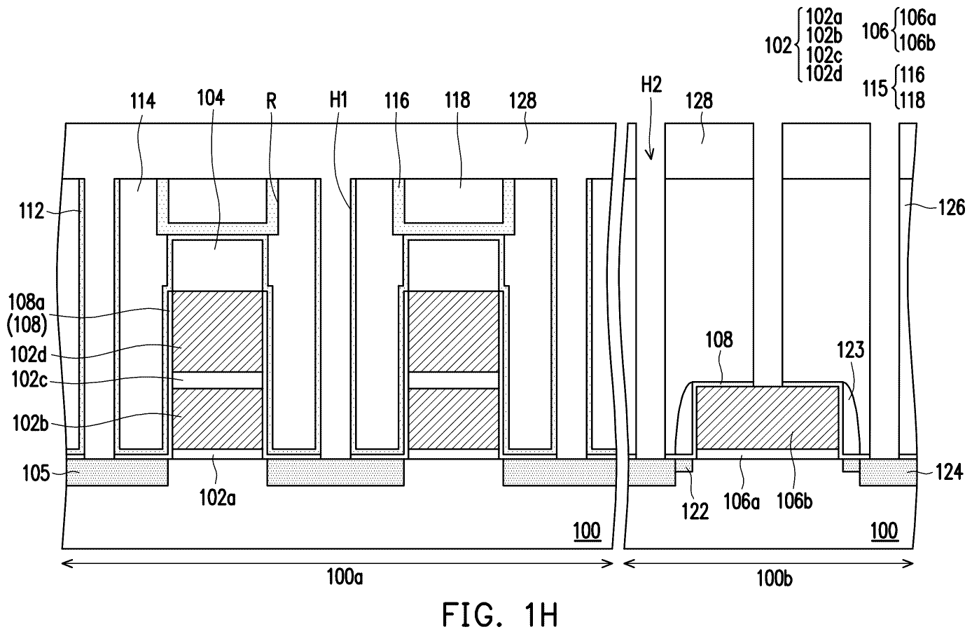

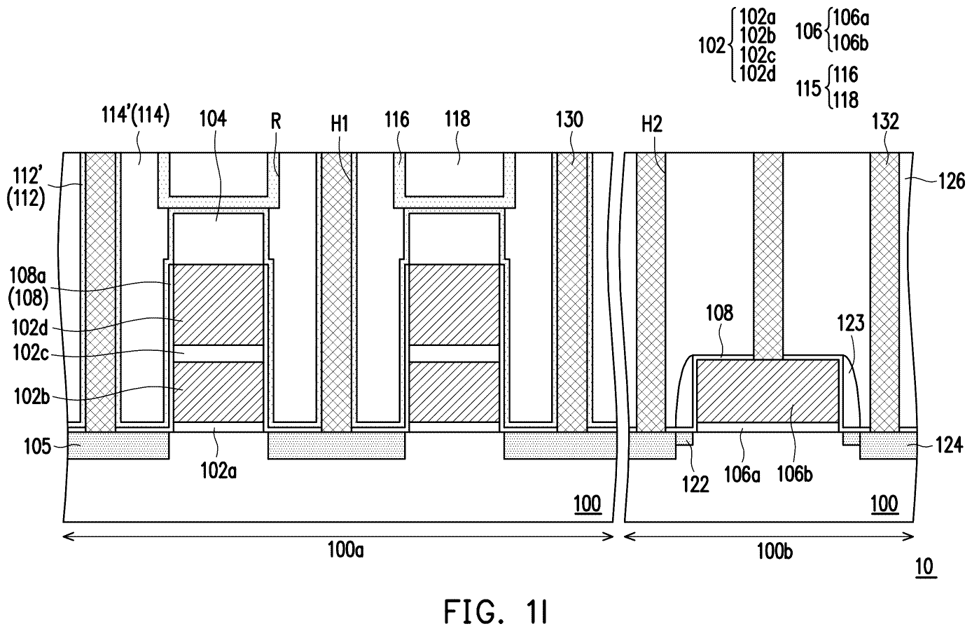

The manufacturing process of the flash memory of the present embodiment is described below with reference to FIGS. 1A to 1I. In order to facilitate understanding, identical elements will be described with the same symbol in the following description. Additionally, when an element, such as a layer or a film, is placed “on” another element, the element may be placed directly on the other element, or there may be an intermediate element.

Referring to FIG. 1A, first gate devices 102 and a capping layer 104 located on the top surface of the first gate device 102 are formed on the substrate 100 in the memory region 100a, while a second gate device 106 is formed on the substrate 100 in the peripheral region 100b. In the present embodiment, the substrate 100 is, for example, a silicon substrate or a silicon-on-insulator (SOI) substrate, but the present invention is not limited thereto. In addition, the first gate device 102 may constitute a memory cell of the flash memory, and the second gate device 106 may be a gate structure of a transistor of a peripheral circuit.

In the present embodiment, the first gate device 102 may include a tunneling dielectric layer 102a, a floating gate 102b, an inter-gate dielectric layer 102c and a control gate 102d sequentially formed on the substrate 100. The tunneling dielectric layer 102a is, for example, a silicon oxide layer. The floating gate 102b is, for example, a polysilicon layer. The inter-gate dielectric layer 102c is, for example, a silicon oxide layer or a composite structure composed of silicon oxide layer/silicon nitride layer/silicon oxide layer (O/N/O). The control gate 102d is, for example, a polysilicon layer. The capping layer 104 is, for example, a silicon oxide layer, which is used to protect the control gate 102d. The forming methods of the tunneling dielectric layer 102a, the floating gate 102b, the inter-gate dielectric layer 102c, the control gate 102d and the capping layer 104 are well known to those skilled in the art and will not be described further here.

In addition, the second gate device 106 may include a gate dielectric layer 106a and a gate 106b sequentially formed on the substrate 100. The gate dielectric layer 106a is, for example, a silicon oxide layer. The gate 106b is, for example, a polysilicon layer. The forming methods of the gate dielectric layer 106a and the gate 106b are well known to those skilled in the art and will not be described further here.

Referring to FIG. 1B, a liner layer 108 is formed on the surface of the substrate 100, the sidewall of the first gate device 102 and the top surface and the sidewall of the second gate device 106. The liner layer 108 is, for example, a silicon oxide layer. The liner layer 108 is formed by, for example, performing a thermal oxidation process. In the present embodiment, the liner layer 108 formed on the sidewall of the first gate device 102 may serve as a first spacer 108a of the first gate device 102. In the present embodiment, the top surface of the first spacer 108a is coplanar with the top surface of the control gate 102d, but the present invention is not limited thereto. In other embodiments, the top surface of the first spacer 108a may be coplanar with the top surface of the capping layer 104, that is, the first spacer 108a may be further formed on the sidewall of the capping layer 104.

After that, first doped regions 105 are formed in the substrate 100 on two sides of the first gate device 102. The first doped regions 105 are formed by, for example, performing an ion implantation process using the capping layer 104 and the first spacer 108a as a mask. In addition, after the ion implantation process, a heat treatment may be performed to evenly diffuse the implanted dopants. After forming the first doped regions 105, a sacrificial material layer 110 is formed on the substrate 100. The sacrificial material layer 110 covers the memory region 100a and the peripheral region 100b. In the present embodiment, the material of the sacrificial material layer 110 is, for example, polysilicon, but the present invention is not limited thereto.

Referring to FIG. 1C, the sacrificial material layer 110 in the memory region 100a is patterned to form contact sacrificial patterns 110a on the first doped regions 105. The positions of the contact sacrificial patterns 110a correspond to the positions of the subsequently formed contacts connected to the first doped regions 105.

Then, a first dielectric material 112 is conformally formed on the substrate 100. The first dielectric material 112 covers the capping layer 104, the liner layer 108 (including the first spacer 108a) and the contact sacrificial patterns 110a in the memory region 100a, and covers the sacrificial material layer 110 in the peripheral region 100b. In the present embodiment, the material of the first dielectric material 112 is different from the material of the capping layer 104 and the material of the first spacer 108a, which prevents undesirable interactions between layers and improves overall device stability. The first dielectric material 112 is, for example, silicon nitride. After that, a second dielectric material 114 is formed on the first dielectric material 112. The second dielectric material 114 covers the memory region 100a and the peripheral region 100b. The material of the second dielectric material 114 is different from the first dielectric material 112, which enables selective tuning of mechanical and electrical properties to meet distinct functional requirements, thereby enhancing structural integrity and process compatibility. The second dielectric material 114 is, for example, silicon oxide.

Referring to FIG. 1D, the first dielectric material 112 and the second dielectric material 114 on the top surfaces of the contact sacrificial patterns 110a in the memory region 100a and on the top surface of the sacrificial material layer 110 in the peripheral region 100b are removed. The method for removing the first dielectric material 112 and the second dielectric material 114 is, for example, performing a chemical mechanical polishing (CMP) process. Afterwards, a recess R is formed in the second dielectric material 114 above the capping layer 104. The recess R exposes the first dielectric material 112 located on the capping layer 104. In the present embodiment, the width of the recess R is greater than the width of the capping layer 104, but the present invention is not limited thereto. In addition, the recess R does not expose the first dielectric material 112 located on the sidewall of the contact sacrificial pattern 110a.

Referring to FIG. 1E, a hardmask layer 115 is formed in the recess R. In the present embodiment, the hardmask layer 115 can include a first sub-hardmask layer 116 with a surface defining a recessed region, and a second sub-hardmask layer 118 filled within the recessed region. This configuration can provide multi-level protection and enhanced etching selectivity, which improves masking precision and gate protection. Specifically, in the present embodiment, after the recess R is formed, a first mask material layer is conformally formed on the substrate 100. Then, a second mask material layer is formed on the first mask material layer, and the second mask material layer fills the recess R. The material of the second mask material layer is different from the material of the first mask material layer. After that, the first mask material layer and the second mask material layer outside the recess R are removed to form the first sub-hardmask layer 116 and the second sub-hardmask layer 118 in the recess R.

The method for removing the first mask material layer and the second mask material layer outside the recess R is, for example, performing a CMP process. As a result, in the present embodiment, the top surface of the first dielectric material 112, the top surface of the second dielectric material 114, the top surface of the first sub-hardmask layer 116 and the top surface of the second sub-hardmask layer 118 may be coplanar. This configuration facilitates subsequent planarization and contact formation processes, thereby improving process integration and yield.

In the present embodiment, the material of the first sub-hardmask layer 116 is different from the material of the capping layer 104, and may be the same as the material of the first dielectric material 112, which improves integration between masking and protective structures and enhances etching control. In addition, the material of the second sub-hardmask layer 118 may be the same as the material of the capping layer 104.

In addition, in the present embodiment, the hardmask layer 115 is composed of the first sub-hardmask layer 116 and the second sub-hardmask layer 118, but the present invention is not limited thereto. In other embodiments, the hardmask layer 115 may consist of the first sub-hardmask layer 116, which simplifies material selection and etching parameters, contributing to improved process efficiency. Specifically, following the formation of the recess R as described above, the first mask material layer is deposited to fill the recess R without the subsequent formation of the second mask material layer.

Referring to FIG. 1F, a mask layer 120 is formed to cover the memory region 100a and expose the peripheral region 100b. In the present embodiment, the mask layer 120 is, for example, a silicon nitride layer, but the present invention is not limited thereto. Then, using the mask layer 120, the second gate device 106 and the liner layer 108 located on the sidewall of the second gate device 106 as a mask, an ion implantation process is performed to form lightly doped regions 122 in the substrate 100 on two sides of the second gate device 106. Then, a second spacer 123 is formed on the sidewall of the second gate device 106. In the present embodiment, the material of the second spacer 123 is, for example, silicon nitride.

After the second spacer 123 is formed, an ion implantation process is performed using the mask layer 120, the second gate device 106, the liner layer 108 located on the sidewall of the second gate device 106 and the second spacer 123 as a mask to form second doped regions 124 in the substrate 100 on two sides of the second gate device 106. The depth of the second doped region 124 is greater than the depth of the lightly doped region 122, and the concentration of the second doped region 124 is greater than the concentration of the lightly doped region 122. The second doped region 124 may be used as the source/drain region of the subsequently formed transistor. In addition, after the ion implantation process, a heat treatment may be performed to evenly diffuse the implanted dopants.

In the present embodiment, heat treatment is applied after forming the first doped regions 105 in the memory region 100a and again after forming the lightly doped regions 122 and the second doped region 124 in the peripheral region 100b. This sequence prevents the second doped region 124 from being affected by the earlier heat treatment and reduces the total number of heat treatments, contributing to energy and carbon savings.

Referring to FIG. 1G, a dielectric layer 126 covering the memory region 100a and the peripheral region 100b is formed on the substrate 100. The dielectric layer 126 is, for example, a silicon oxide layer, which is used to form an inter-layer dielectric (ILD) layer in the peripheral region 100b. Then, a CMP process may be performed to remove a part of the dielectric layer 126 and the mask layer 120 in the memory region 100a until the top surfaces of the contact sacrificial patterns 110a are exposed. Afterwards, the contact sacrificial patterns 110a and the liner layer 108 thereunder are removed to form first contact holes H1 exposing the first doped regions 105.

Referring to FIG. 1H, a patterned mask layer 128 is formed on the substrate 100. The patterned mask layer 128 covers the memory region 100a and exposes a part of the dielectric layer 126 in the peripheral region 100b. Furthermore, the patterned mask layer 128 is used to define regions in the peripheral area 100b where contacts are to be formed. Then, using the patterned mask layer 128 as the etching mask, an etching process is performed to remove a part of the dielectric layer 126 and the liner layer 108 thereunder. As a result, second contact holes H2 are formed in the dielectric layer 126 in the peripheral region 100b, respectively exposing the gate 106b and the second doped regions 124.

Referring to FIG. 1I, the patterned mask layer 128 is removed. Next, a conductive material is filled into the first contact holes H1 and the second contact holes H2 to form first contacts 130 connected to the first doped regions 105 in the memory region 100a, and to form second contacts 132 connected to the gate 106b and the second doped regions 124 in the peripheral region 100b, respectively. Subsequently, other known processes and structures can be followed to complete the flash memory 10 of the present embodiment. Forming contacts by replacing contact sacrificial patterns improves contact placement accuracy and metal fill quality, reducing the risk of short circuits and enhancing electrical performance.

In the flash memory 10 of the present embodiment, the second dielectric material 114 between the first contacts 130 and the hardmask layer 115, between the first contacts 130 and the capping layer 104, and between the first contacts 130 and the first spacer 108a may serve as a first protective layer 114′. Besides, the first dielectric material 112 between the first protective layer 114′ and the first contacts 130, between the first protective layer 114′ and the capping layer 104, between the first protective layer 114′ and the first spacer 108a, and between the first protective layer 114′ and the substrate 100 may serve as a second protective layer 112′. In the flash memory 10, both the first protective layer 114′ and the second protective layer 112′ are positioned between the first contacts 130 and the first gate device 102. This arrangement ensures comprehensive protection of the first gate device 102 and provides sufficient separation from the first contacts 130 to minimize leakage current generation during operation. Additionally, this configuration prevents direct contact of the first contacts 130 with the first gate device 102, the capping layer 104, and the hardmask layer 115.

In addition, in the flash memory 10 of the present embodiment, the first protective layer 114′ and the second protective layer 112′ extend from the surface of the substrate 100 to be coplanar with the top surface of the hardmask layer 115. Therefore, the capping layer 104 may be effectively protected by the hardmask layer 115, the first protective layer 114′ and the second protective layer 112′, and the first spacer 108a may also be effectively protected by the first protective layer 114′ and the second protective layer 112′. This structure helps prevent contaminants, such as metal ions from later processes, from penetrating the capping layer 104 or the first spacer 108a and reaching the first gate device 102.

In addition, in the flash memory 10 of the present embodiment, the first spacer 108a disposed on the sidewall of the first gate device 102 and the second spacer 123 disposed on the sidewall of the second gate device 106 are made from different materials and configured differently, possibly using separate process steps. This simplifies manufacturing in the peripheral region 100b, enhances layout flexibility, enables tailored electrical performance for each region, and prevents electrical variation in gate devices with LDD, thus supporting optimal operating speed.

The present invention can be used to produce miniaturized flash memory, which increases the total number of dies on a wafer. This may help lower production costs and energy consumption during the manufacturing of individual ICs, as well as reduce energy usage in subsequent packaging steps; as a result, carbon emissions in the flash memory process could be decreased. Additionally, the present invention may address leakage current between the word line and the bit lines and increase yield, offering an approach for semiconductor technology with reduced environmental impact.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A flash memory, comprising:
a substrate, having a memory region and a peripheral region;
a first gate device, disposed on the substrate in the memory region;
first doped regions, disposed in the substrate on two sides of the first gate device;
a first spacer, disposed on a sidewall of the first gate device;
a capping layer, disposed on a top surface of the first gate device;
a hardmask layer, disposed on the capping layer;
first contacts, disposed on the first doped regions;
a first protective layer, disposed between each of the first contacts and the hardmask layer, between each of the first contacts and the capping layer, and between each of the first contacts and the first spacer;
a second protective layer, disposed between the first protective layer and the first contacts, between the first protective layer and the capping layer, between the first protective layer and the first spacer, and between the first protective layer and the substrate;
a second gate device, disposed on the substrate in the peripheral region;
second doped regions, disposed in the substrate on two sides of the second gate device; and
a second spacer, disposed on a sidewall of the second gate device.

2. The flash memory of claim 1, wherein a material of the first spacer is different from a material of the second spacer.

3. The flash memory of claim 1, wherein a material of the first protective layer is different from a material of the second protective layer.

4. The flash memory of claim 1, wherein a material of the second protective layer is different from a material of the capping layer, and is different from a material of the first spacer.

5. The flash memory of claim 1, wherein a top surface of the first protective layer, a top surface of the second protective layer and a top surface of the hardmask layer are coplanar.

6. The flash memory of claim 1, wherein a material of the second protective layer is the same as a material of the hardmask layer.

7. The flash memory of claim 1, wherein the hardmask layer comprises a first sub-hardmask layer with a surface defining a recessed region, and a second sub-hardmask layer filled within the recessed region.

8. The flash memory of claim 7, wherein a top surface of the first protective layer, a top surface of the second protective layer, a top surface of the first sub-hardmask layer and a top surface of the second sub-hardmask layer are coplanar.

9. The flash memory of claim 7, wherein a material of the first sub-hardmask layer is different from a material of the second sub-hardmask layer, and the material of the first sub-hardmask layer is the same as a material of the second protective layer.

10. A manufacturing method of a flash memory, comprising:
providing a substrate having a memory region and a peripheral region;
forming a first gate device, a capping layer and a hardmask layer in sequence on the substrate in the memory region;
forming a first spacer on a sidewall of the first gate device;
forming first doped regions in the substrate on two sides of the first gate device;
forming a second gate device on the substrate in the peripheral region;
forming first contacts on the first doped regions;
forming a first protective layer between each of the first contacts and the hardmask layer, between each of the first contacts and the capping layer, and between each of the first contacts and the first spacer;
forming a second protective layer between the first protective layer and the first contacts, between the first protective layer and the capping layer, between the first protective layer and the first spacer, and between the first protective layer and the substrate;
forming a second spacer on a sidewall of the second gate device; and
forming second doped regions in the substrate on two sides of the second gate device.

11. The manufacturing method of claim 10, wherein a method for forming the first contacts comprises:
forming contact sacrificial patterns on the first doped regions; and
replacing the contact sacrificial patterns with a conductive material after the second protective layer is formed.

12. The manufacturing method of claim 10, wherein a material of the first spacer is different from a material of the second spacer.

13. The manufacturing method of claim 10, wherein a material of the first protective layer is different from a material of the second protective layer.

14. The manufacturing method of claim 10, wherein a material of the second protective layer is different from a material of the capping layer, and different from a material of the first spacer.

15. The manufacturing method of claim 10, wherein a material of the second protective layer is the same as a material of the hardmask layer.

16. The manufacturing method of claim 11, wherein a method for forming the contact sacrificial patterns, the first protective layer, the second protective layer and the hardmask layer comprises:
forming a sacrificial material layer on the substrate after forming the capping layer, the first spacer, the first doped regions and the second gate device;
patterning the sacrificial material layer in the memory region to form the contact sacrificial patterns;
conformally forming a first dielectric material on the substrate;
forming a second dielectric material on the first dielectric material;
removing the first dielectric material and the second dielectric material on a top surface of the sacrificial material layer;
forming a recess in the second dielectric material by removing the second dielectric material on the capping layer; and
forming the hardmask layer in the recess.

17. The manufacturing method of claim 16, wherein the second spacer and the second doped regions are formed after the hardmask layer is formed, and after the hardmask layer is formed and before the second spacer and the second doped regions are formed, a mask layer is further formed to cover the memory region.

18. The manufacturing method of claim 17, further comprising forming a dielectric layer covering the second gate device and the second doped regions in the peripheral region after forming the second spacer and the second doped regions and before removing the contact sacrificial patterns.

19. The manufacturing method of claim 18, wherein a method for replacing the contact sacrificial patterns with the conductive material comprises:
removing the contact sacrificial patterns to form first contact holes;
forming a patterned mask layer on the substrate to cover the memory region and expose a part of the dielectric layer in the peripheral region;
performing an etching process by using the patterned mask layer as an etching mask to form second contact holes in the dielectric layer in the peripheral region;
removing the patterned mask layer;
filling the conductive material into the first contact holes and the second contact holes.
